(19) United States
(12) Patent Application Publication
(10) Pub. No.: US 2025/0277874 A1
(43) Pub. Date: Sep. 4, 2025

(54) POWER SUPPLY DETECTION APPARATUS AND CABINET

(71) Applicant: Fulian Precision Electronics (Tianjin) Co., LTD., Tianjin (CN)

(72) Inventors: WEI-MING LEE, New Taipei (TW); CHI-WEN CHEN, New Taipei (TW)

(21) Appl. No.: 18/959,922

(22) Filed: Nov. 26, 2024

(30) Foreign Application Priority Data
Mar. 4, 2024 (CN) 202410244029.8

(51) Int. Cl. G01R 31/42; H05K 7/14

(52) U.S. Cl. CPC G01R 31/42; H05K 7/1492

(57) ABSTRACT

A power supply detection apparatus includes a casing, a power shelf connector, a copper bar, and a transformer. The power shelf connector is electrically connected to the power shelf. The power shelf provides a power supply to a load through the power supply detection apparatus. The copper bar is fixedly connected to the power shelf connector. The cooper bar includes a first bent component and a second bent component. The first bent component and the second component are bent relative to each other and form a cavity. The transformer extends through the cavity. The transformer detects an output current and/or an output voltage of the power shelf. A cabinet is also provided, which can conveniently and quickly detect the current and the voltage outputted by the power shelf.

### TECHNICAL FIELD

The present application generally relates to server cabinet technology, and particularly to a power supply detection apparatus and a cabinet.

### BACKGROUND

With a development in technologies, such as big data and artificial intelligence, servers in a large-scale are widely used. The servers are usually powered by a cabinet. The cabinet includes an alternating current (AC) power supply, a power shelf, and a female cable for connecting with the servers. However, detections of a current and/or a voltage outputted by the power shelf may be problematic.

There is room for improvement in the art.

### BRIEF DESCRIPTION OF THE DRAWINGS

Implementations of the present application will now be described, by way of example only, with reference to the attached figures.

FIG. 1 is a diagram illustrating an embodiment of a cabinet according to the present application.

FIG. 2 is a diagram illustrating a first embodiment of a power supply detection apparatus according to the present application.

FIG. 3 is a diagram illustrating a second embodiment of a power supply detection apparatus according to the present application.

FIG. 4 is a diagram illustrating of the power supply detection apparatus of FIG. 3, viewed from another perspective according to the present application.

### DETAILED DESCRIPTION

The following clearly describes the technical solution in embodiments of this application with reference to the accompanying drawings in the embodiments of the application.

It is understood that, the connection relationship described in this application is a direct connection or an indirect connection. For example, that A is connected to B may not only be that A is directly connected to B, but also be that A is indirectly connected to B by one or more other electrical components. For example, it may be that A is directly connected to C, and C is directly connected to B. In this way, A is connected to B by C. It may be further understood that “A is connected to B” described in this application may be that A is directly connected to B, or maybe that A is indirectly connected to B by one or more other electrical components.

In the description of the present disclosure, unless other specified, “/” means “or”. For example, A/B may indicate A or B. In this application, “and/or” describes only an association relationship for describing associated objects and indicates that three relationship may exist. For example, A and/or B may indicate the following three cases: Only A exists, both A and B exist, and only B exists.

In the description of the present disclosure, the words such as “first”, “second”, and the like, are used to distinguish different objects, and do not limit quantities and execution sequences. In addition, the words such as “first”, “second”, do not necessarily limit a definite difference. In addition, terms “include” and “have”, and any variant thereof are intended to cover the non-exclusive inclusion.

With a development in technologies, such as big data and artificial intelligence, servers in a large-scale are widely used. The servers are usually powered by a cabinet. The cabinet includes an alternating current (AC) power supply, a power shelf, and a female cable for connecting with the servers. However, how to detect a current and/or a voltage outputted by the power shelf becomes a problem.

Therefore, the present application provides a power source detection apparatus and a cabinet, which is conveniently and quickly detect a current and/or a voltage outputted by the power shelf, and which has a highly integrated and is suitable for an application scenario with a small volumetric requirement.

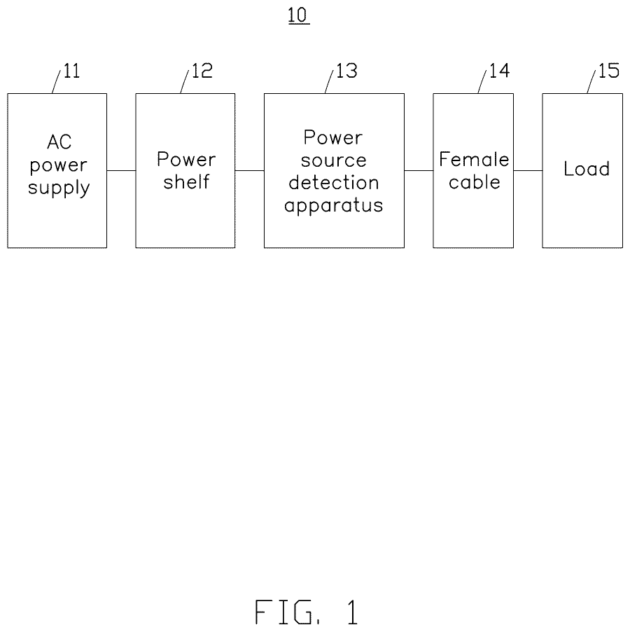

In detail, referring to FIG. 1, FIG. 1 shows a diagram illustrating the cabinet 10 provided by the present application. The cabinet 10 includes an alternating current (AC) power supply 11, a power shelf 12, a power supply detection apparatus 13, a female cable 14, and a load 15.

The AC power supply 11 is electrically connected to the power shelf 12. The AC power supply is configured to output an AC to the power shelf 12.

The power shelf 12 is electrically connected to the power supply detection apparatus 13 through the female cable 14. The power shelf is configured to convert and output the AC outputted by the AC power supply 11. For example, the power shelf 12 may include at least one AC/DC module, for converting the received AC into a direct current and then to output. For another example, the power shelf 12 may include at least one power distribution unit (PDU), for implementing a distribution of the received AC and a fault protection, and the like.

The power supply detection apparatus 13 is configured to detect parameters of electrical signals outputted by the power shelf 12. For example, the power supply detection apparatus 13 may detect an output current, an output voltage, an output power of the power shelf 12, and the like. Therefore, by detecting the parameters of the electrical signals outputted by the power shelf 12, situations of whether a working state of the power shelf 12 is abnormal, the electrical signals outputted by the power shelf 12 is overvoltage, overcurrent, and overloaded, may be determined.

The female cable 14 is electrically connected to the load 15. The female cable 14 is configured to transfer the electrical signals outputted by the power shelf 12 to the load 15, for powering on the load 15 by the power shelf 12. The load 15 may be an electrical device of electrical consuming, such as servers, distribution panels. The number of the load 15 may be multiple, the multiple of the loads 15 are electrically connected to the female cable 14, for receiving a power supply voltage and a power supply current provided by the power shelf 12.

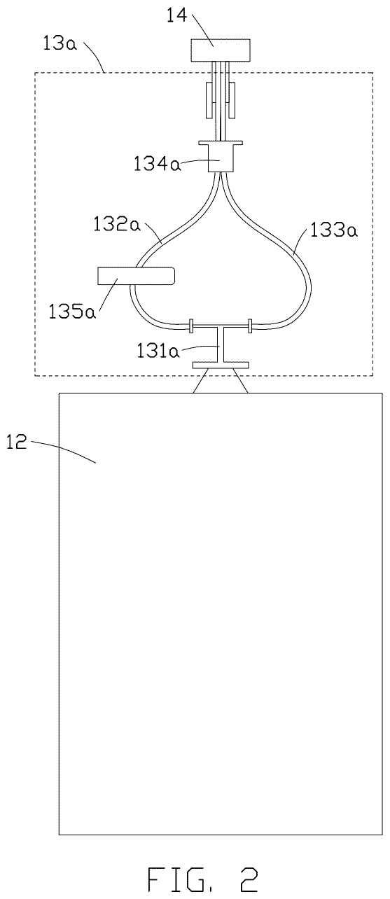

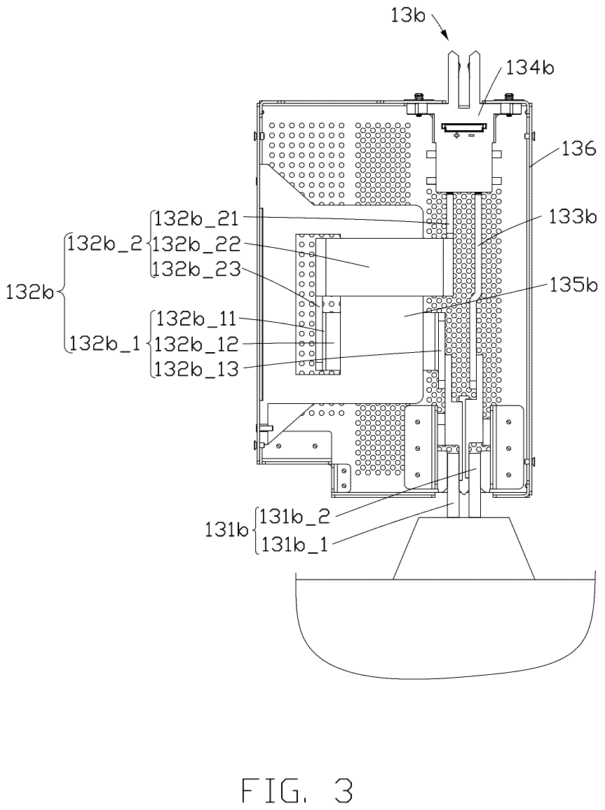

The power supply detection apparatus 13 may include several structures. Description will be made with reference to the power supply detection apparatus 13a shown in FIG. 2, and the power supply detection apparatus 13b as shown in FIG. 3 as examples. The present application does not limit the structure type of the power supply detection apparatus 13.

Referring to FIG. 2, FIG. 2 shows a first embodiment of a structure of the power supply detection apparatus 13a provided by the present application. The power supply detection apparatus 13a includes a power shelf connector 131a, a positive copper wire 132a, a negative copper wire 133a, a female cable connector 134a, and a transformer 135a.

The power shelf connector 131a is configured to electrically connect with an output terminal of the power shelf 12. The power shelf connector 131a is made of metal material, and is in an I-shape. The power shelf connector 131a includes a first output portion 131a_1 and a second output portion 131a_2. The first output portion 131a_1 is electrically connected to one of the positive copper wire 132a and the negative copper wire 133a, and the second output portion 131a_2 is electrically connected to another of the positive copper wire 132a and the negative copper wire 133a.

In some embodiments, each of the first output portion 131a_1 and the second output portion 131a_2 define at least one through hole, a terminal of each of the positive copper wire 132a and the negative copper wire 133a connected to the first output portion 131a_1 or the second output portion 131a_2 is set with a fastener, such as a bolt, a nut, a screw, a washer, a rivet, and the like, thus the terminal of each of the positive copper wire 132a and the negative copper wire 133a is connected to the power shelf connector 131a through the at least one through hole of the positive copper wire 132a and the negative copper wire 133a.

The terminal of each of the positive copper wire 132a and the negative copper wire 133a is connected to the first output portion 131a_1 or the second output portion 131a_2 through the corresponding faster, another terminal of each of the positive copper wire 132a and the negative copper wire 133a is bundled in the female cable connector 134a. For matching with a larger output current of the power shelf 12, both of the positive copper wire 132a and the negative copper wire 133a are set to include a copper bundle with multiple copper wires.

The female cable connector 134a is configured to connect with the female cable 14. The female cable connector 134a may be a clip connector, a bus bar connector, and the like.

The transformer 135a extends through the positive copper wire 132a or the negative copper wire 133a. The transformer 135a is configured to measure a current passing through the positive copper wire 132a or the negative copper wire 133a and/or a voltage passing through the positive copper wire 132a or the negative copper wire 133a, for obtaining outputting parameters of the power shelf 12. The transformer 135a may be a current transformer, or a voltage transformer, and the like. Therefore, there is no need to set with a current/voltage sensor being connected to the positive copper wire 132a or the negative copper wire 133a for obtaining the corresponding current or the voltage. The circuit structure of the power supply detection apparatus 13a is simplified, and a failure rate of the power supply detection apparatus 13a is decreased.

Referring to FIG. 3, FIG. 3 shows a second embodiment of the power supply detection apparatus 13b provided by the present application. The power supply detection apparatus 13b includes a power shelf connector 131b, a positive copper bar 132b, a negative copper bar 133b, a female cable connector 134b, a transformer 135b, and a casing 136. All of the power shelf connector 131b, the positive copper bar 132b, the negative copper bar 133b, the female cable connector 134b, and the transformer 135b are received in the casing 136.

The power shelf connector 131b includes a first connection portion 131b_1 and a second connection portion 131b_2. Both of the first output portion 131b_1 and the second output portion 131b_2 are made of metal material. The first connection portion 131b_1 is electrically connected to the positive copper bar 132b, and the second connection portion 131b_2 is electrically connected to the negative copper bar 133b.

In some embodiments, each of the first connection portion 131b_1 and the second connection portion 131b_2 define at least one through hole, a terminal of each of the positive copper bar 132b and the negative copper bar 133b connected to the first connection portion 131b_1 or the second connection portion 131b_2 is set with a fastener, such as a bolt, a nut, a screw, a washer, a rivet, and the like, thus the terminal of each of the positive copper bar 132b and the negative copper bar 133b is connected to the power shelf connector 131b through the at least one through hole of the positive copper bar 132b and the negative copper bar 133b.

The positive copper bar 132b includes a first bent component 132b_1 and a second bent component 132b_2. The first bent component 132b_1 includes a first bent portion 132b_11, a second bent portion 132b_12, and a third bent portion 132b_13. The second bent component 132b_2 includes a fourth bent portion 132b_21, a fifth bent portion 132b_22, and a sixth bent portion 132b_23.

A surface of the first bent portion 132b_11 is connected to the first connection portion 131b_1 of the power shelf connector 131b. Another surface of the first bent portion 132b_11 is perpendicularly connected to a sidewall of the second bent portion 132b_12. Another opposite sidewall of the second bent portion 132b_12 is perpendicularly connected to a first sidewall of the third bent portion 132b_13. That is, the first bent portion 132b_11 is parallel to the third bent portion 132b_13.

The third bent portion 132b_13 is integrally formed with the fourth bent portion 132b_21. The first sidewall of the third bent portion 132b_13 is a first sidewall of the fourth bent portion 132b_21. A second sidewall of the fourth bent portion 132b_21 is a sidewall opposite to the first sidewall. The second sidewall of the fourth bent portion 132b_22 is perpendicularly connected to a sidewall of the fifth bent portion 132b_22. That is, the fifth bent portion 132b_22 is parallel with the second bent portion 132b_12.

An opposite sidewall of the fifth bent portion 132b_22 is perpendicularly connected to the sixth bent portion 132b_23. The sixth bent portion 132b_23 is connected to a positive electrode terminal of the female cable connector 134b. A negative electrode terminal of the female cable connector 134b is electrically connected to the second connection portion 131b_2 of the power shelf connector 131b through the negative copper bar 133b.

Therefore, by comparing with the power supply detection apparatus 13a with the positive copper wire 132a and the negative copper wire 133a in FIG. 2, the power supply detection apparatus 13b in FIG. 3 uses the positive copper bar 132b and the negative copper bar 133b, a surface area of a conductor is obviously increased, therefore, it is more easier to match with a larger output current of the power shelf 12, and a cost of wire cables is saved.

Because of the second bent portion 132b_12 being parallel with the fifth bent portion 132b_22, and the second bent portion 132b_12 being connected to the fifth bent portion 132b_22 through the third bent portion 132b_13 and the fourth bent portion 132b_21, the second bent portion 132b_12, the third bent portion 132b_23, the fourth bent portion 132b_21, and the fifth bent portion 132b_22 form a cavity.

The transformer 135b extends through the cavity formed by the second bent portion 132b_12, the third bent portion 132b_23, the fourth bent portion 132b_21, and the fifth bent portion 132b_22. Therefore, the positive copper bar 132b includes multiple bent portions, for electrically connecting the power shelf connector 131b with the female cable connector 134b. By comparing with the power supply detection apparatus 13a with the positive copper wire 132a and the negative copper wire 133a in FIG. 2, a height of each of the positive copper bar 132b and the negative copper bar 133b in the power supply detection apparatus 13b in FIG. 3 is reduced, a sum height of the transformer 135b and the positive copper bar 132b is not decided by a heigh of the copper bundle added with a height of the transformer 135a, but is decided by a height of the third bent portion 132b_13. Therefore, a height of the casing 136 may be set to be lower, for decreasing a sum height and a volume of the power source detection apparatus 13b, and the power source detection apparatus 13b may be matched with the cabinet 10 with a lower height, thus a adaptability of the power source detection apparatus 13b is improved.

In addition, because of the power source detection apparatus 13b with the casing 136 is an integrative apparatus. By comparing with the power source detection apparatus 13a, the power shelf connector 131b in the power source detection apparatus 13b is not manually connected to the power shelf 12, and then the positive copper wire 132a and the negative copper wire 133b are manually connected to the power shelf connector 131b. Therefore, the assembly and operation steps are simplified, and an assembly efficiency of the power source detection apparatus 13b is improved.

The structure of the female cable connector 134b is the same as the female cable connector 134a, the details will not be described again.

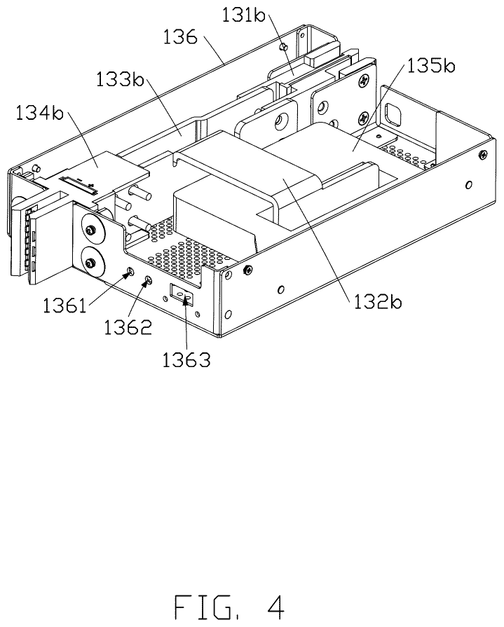

Referring to FIG. 4, FIG. 4 shows the power supply detection apparatus 13b of FIG. 3 from another perspective provided by the present application.

In some embodiments, the casing 136 further includes a first output terminal 1361 and a second output terminal 1362. The first output terminal 1361 and the second output terminal 1362 are electrically connected to the transformer 135b. The first output terminal 1361 is an output terminal of a voltage signal of the transformer 135b, and the second output terminal 1362 is an output terminal of a current signal of the transformer 135b. The first output terminal 1361 and the second output terminal 1362 may be connected to an oscilloscope. Waveforms of the voltage signal and the current signal are displayed on the oscilloscope. Thus, the parameters of the power shelf 12 are obtained, such as the output voltage, the output current, and the output power, and the like.

In some embodiments, the casing 136 also includes a voltage input terminal 1363. The voltage input terminal 1363 is also connected to the transformer 135b. The voltage input terminal 1363 may be connected to an external power supply. The external power supply may provide a power supply to the transformer 135b through the voltage input terminal 1363.

Therefore, the power supply detection apparatus 13 and the cabinet 10 provided by the present application, may be conveniently and quickly detect electrical parameters, such as a current and a voltage outputted by the power shelf 12.

Those skilled in the art will recognize that the above described embodiments are only intended to illustrate the invention and are not intended to limit the invention, and numerous possible modifications and variations within the spirit of the invention will fall within the scope of the invention.

What is claimed is:

1. A power supply detection apparatus comprises:
a casing;
a power shelf connector electrically connected to a power shelf and configured to receive a power supply from the power shelf;
a cooper bar fixedly connected to the power shelf connector, and comprising a first bent component and a second bent component; the first bent component and the second component bent relative to each other to form a cavity; and
a transformer extending through the cavity and configured to detect an output current and/or an output voltage of the power shelf.

2. The power supply detection apparatus of claim 1, wherein the first bent component comprises a first bent portion, a second bent portion, and a third bent portion; a surface of the first bent portion is connected to the first connection portion of the power shelf connector; another surface of the first bent portion is perpendicularly connected to a sidewall of the second bent portion; a sidewall of the second bent portion, opposite to the sidewall of the second bent portion connected to the first bent portion, is perpendicularly connected to a first sidewall of the third bent portion; the first bent portion is parallel to the third bent portion.

3. The power supply detection apparatus of claim 2, wherein the second bent component comprises a fourth bent portion and a fifth bent portion; the third bent portion is integrally formed with the fourth bent portion; a sidewall of the fourth bent portion, opposite to the first sidewall of the third bent portion, is perpendicularly connected to a first sidewall of the fifth bent portion; the fifth bent portion is parallel with the second bent portion.

4. The power supply detection apparatus of claim 3, wherein the cavity is further defined between the second bent portion, the third bent portion, the fourth bent portion, and the fifth bent portion.

5. The power supply detection apparatus of claim 3, wherein the second bent component further comprises a sixth bent portion; the sixth bent portion is perpendicularly connected to a second sidewall of the fifth bent portion opposite to the first sidewall of the fifth bent portion.

6. The power supply detection apparatus of claim 5, wherein the power supply detection apparatus further comprises a female cable connector; the female cable connector is configured to be connected with a female cable; the female cable connector is fixedly connected to the sixth bent portion.

7. The power supply detection apparatus of claim 1, wherein the power shelf connector defines at least one through hole; the cooper bar is fixedly connected to the power shelf connector with a fastener through the at least one through hole.

8. The power supply detection apparatus of claim 1, wherein the casing further comprises a first output terminal and a second output terminal; the first output terminal and the second output terminal are electrically connected to an oscilloscope; the transformer outputs a voltage signal through the first output terminal, and/or output a current signal through the second output terminal to indicate respectively an output voltage and/or an output current of the power shelf.

9. The power supply detection apparatus of claim 1, wherein the casing further comprises a voltage input terminal; the voltage input terminal is connected between with the transformer and an external power supply; the voltage input terminal transmits a power supply provided by the external power supply to the transformer.

10. A cabinet comprises:
a power shelf,
a female cable; and
a power supply detection apparatus comprising:
a casing;
a power shelf connector electrically connected to a power shelf and configured to receive a power supply from the power shelf;
a cooper bar fixedly connected to the power shelf connector, and comprising a first bent component and a second bent component; the first bent component and the second component bent relative to each other to form a cavity; and
a transformer extending through the cavity and configured to detect an output current and/or an output voltage of the power shelf.

11. The cabinet of claim 10, wherein the first bent component comprises a first bent portion, a second bent portion, and a third bent portion; a surface of the first bent portion is connected to the first connection portion of the power shelf connector; another surface of the first bent portion is perpendicularly connected to a sidewall of the second bent portion; a sidewall of the second bent portion, opposite to the sidewall of the second bent portion connected to the first bent portion, is perpendicularly connected to a first sidewall of the third bent portion; the first bent portion is parallel to the third bent portion.

12. The cabinet of claim 11, wherein the second bent component comprises a fourth bent portion and a fifth bent portion; the third bent portion is integrally formed with the fourth bent portion; a sidewall of the fourth bent portion, opposite to the first sidewall of the third bent portion, is perpendicularly connected to a first sidewall of the fifth bent portion; the fifth bent portion is parallel with the second bent portion.

13. The cabinet of claim 12, wherein the second bent portion, the third bent portion, the fourth bent portion, and the fifth bent portion form the cavity.

14. The cabinet of claim 12, wherein the second bent component further comprises a sixth bent portion; the sixth bent portion is perpendicularly connected to a second sidewall of the fifth bent portion opposite to the first sidewall of the fifth bent portion.

15. The cabinet of claim 14, wherein the power supply detection apparatus further comprises a female cable connector; the female cable connector is configured to connect with a female cable; the female cable connector is fixedly connected to the sixth bent portion.

16. The cabinet of claim 10, wherein the power shelf connector defines at least one through hole; the cooper bar is fixedly connected to the power shelf connector with a fastener through the at least one through hole.

17. The cabinet of claim 10, wherein the casing further comprises a first output terminal and a second output terminal; the first output terminal and the second output terminal are electrically connected to an oscilloscope; the transformer outputs a voltage signal through the first output terminal, and/or output a current signal through the second output terminal; the voltage signal and the current signal are configured to indicate an output voltage and/or an output current of the power shelf.

18. The cabinet of claim 10, wherein the casing further comprises a voltage input terminal; the voltage input terminal is connected between with the transformer and an external power supply; the voltage input terminal transmits a power supply provided by the external power supply to the transformer.
